(19) United States
(12) Patent Application Publication
(10) Pub. No.: US 2026/0075842 A1
(43) Pub. Date: Mar. 12, 2026

(54) SEMICONDUCTOR DEVICE HAVING ELECTRODE STRUCTURES

(71) Applicant: SK hynix Inc., Gyeonggi-do (KR)

(72) Inventor: Jeong Hwan SONG, Gyeonggi-do (KR)

(21) Appl. No.: 19/211,284

(22) Filed: May 19, 2025

(30) Foreign Application Priority Data
Sep. 10, 2024 (KR) 10-2024-0123247

(51) Int. Cl. H10B 63/00

(52) U.S. Cl. CPC H10B 63/80; H10B 63/24

(57) ABSTRACT

A semiconductor device includes a cell area; a first peripheral circuit area adjacent to a first side of the cell area in a first direction; and a second peripheral circuit area adjacent to a second side of the cell area in a second direction. The first direction and the second direction are perpendicular to each other. The cell area includes a first sub-area including a first memory cell; and a second sub-area including a second memory cell. The first memory cell includes a first electrode structure. The second memory cell includes a second electrode structure. The first electrode structure includes a first lower electrode and a first upper electrode. The second electrode structure includes a second lower electrode and a second upper electrode. The first lower electrode is thicker than the second lower electrode. The first upper electrode is thinner than the second upper electrode.

### CROSS-REFERENCE TO RELATED APPLICATIONS

The present application claims priority under 35 U.S.C. 119(a) to Korean Patent Application No. 10-2024-0123247, filed on Sep. 10, 2024, which is incorporated herein by reference in its entirety.

### BACKGROUND

### 1. Field

Embodiments of the present disclosure relate generally to a semiconductor technology, and more particularly, to a semiconductor device including memory cells each of which includes a variable resistance device and an electrode structure, and a method for fabricating the same.

### 2. Description of the Related Art

Recent demands for miniaturization, low power consumption, high performance, and diversification of electronic devices require semiconductor devices capable of storing information in various electronic devices, such as computers and portable communication devices and the like, and researchers and the industry are studying to develop such semiconductor devices. Such semiconductor devices include semiconductor devices capable of storing data by using the characteristics of switching between different resistance states according to the applied voltage or current, such as a Resistive Random Access Memory (RRAM), a Phase-change Random Access Memory (PRAM), a Ferroelectric Random Access Memory (FRAM), a Magnetic Random Access Memory (MRAM), and an E-fuse.

### SUMMARY

Embodiments of the present disclosure are directed to decreasing a hold current I-hold of memory cells of a semiconductor device.

Embodiments of the present disclosure are directed to uniformizing characteristics of memory cells of a semiconductor device.

In accordance with an embodiment of the present disclosure, a semiconductor device includes a cell area; a first peripheral circuit area adjacent to a first side of the cell area in a first direction; and a second peripheral circuit area adjacent to a second side of the cell area in a second direction. The first direction and the second direction are perpendicular to each other. The cell area includes a first sub-area including a first memory cell; and a second sub-area including a second memory cell. The first memory cell includes a first electrode structure. The second memory cell includes a second electrode structure. The first electrode structure includes a first lower electrode and a first upper electrode. The second electrode structure includes a second lower electrode and a second upper electrode. The first lower electrode is thicker than the second lower electrode. The first upper electrode is thinner than the second upper electrode.

In accordance with another embodiment of the present disclosure, a semiconductor device includes a cell area, and a first peripheral circuit area adjacent to a first side of the cell area. The cell area includes a first sub-area including a first memory cell and a second sub-area including a second memory cell. The first memory cell is closer to the first peripheral circuit area than the second memory cell. The first memory cell includes a first variable resistance element and a first electrode. The second memory cell includes a second variable resistance element and a second electrode. The first electrode includes a first lower electrode and a first upper electrode. The second electrode includes a second lower electrode and a second upper electrode. The first lower electrode is thicker than the second lower electrode. The first upper electrode is thinner than the second upper electrode.

### BRIEF DESCRIPTION OF THE DRAWINGS

FIG. 1A is a perspective view schematic illustrating a cell array of a semiconductor device in accordance with an embodiment of the present disclosure.

FIG. 1B is a top view schematic illustrating a block arrangement of a semiconductor device in accordance with an embodiment of the present disclosure.

FIGS. 2A to 2D are simplified schematic views illustrating a cell area CA of a semiconductor device including a plurality of sub-areas in accordance with embodiments of the present disclosure.

FIGS. 3A and 3B, FIGS. 4A and 4B, FIGS. 5A and 5B, and FIG. 6 are cross-sectional views and enlarged views illustrating memory cell structures of semiconductor devices in accordance with diverse embodiments of the present disclosure.

FIGS. 7A to 7F are simplified schematic views illustrating a method for forming electrode structures in accordance with embodiments of the present disclosure.

### DETAILED DESCRIPTION

Various embodiments of the present disclosure are described in detail with reference to the accompanying drawings. Specific structural or functional descriptions of the embodiments are provided as examples to describe specific implementations of the technical concepts of the present disclosure. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with these areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

Concepts are disclosed in conjunction with examples and embodiments as described above. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the above descriptions. All changes within the meaning and range of equivalency of the claims are included within their scope.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

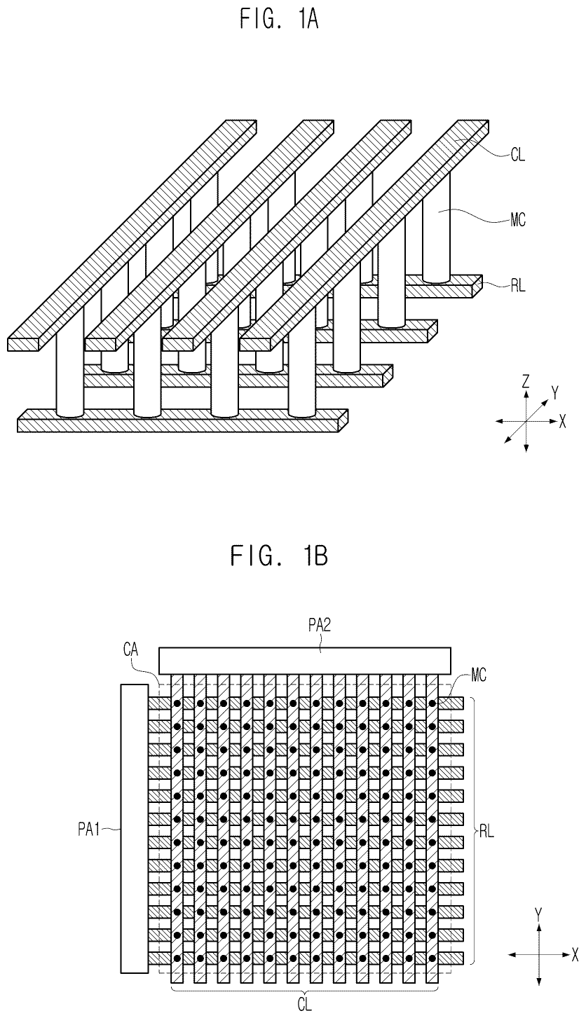

FIG. 1A is a perspective view schematic illustrating a cell array of a semiconductor device in accordance with an embodiment of the present disclosure. FIG. 1B is a top view schematic illustrating a block arrangement of the semiconductor device in accordance with the embodiment of the present disclosure. Referring to FIGS. 1A and 1B, the semiconductor device in accordance with an embodiment of the present disclosure may include a plurality of row interconnection lines RL extending parallel to each other in a first direction X, a plurality of column interconnection lines CL extending parallel to each other in a second direction Y, and memory cells MC disposed at the intersections between the row interconnection lines RL and the column interconnection lines CL. The memory cells MC may be disposed to have a pillar shape extending in a vertical direction Z between the row interconnection lines RL and the column interconnection lines CL. The first direction X, the second direction Y, and the vertical direction Z may be perpendicular to each other. In FIG. 1B, in order to facilitate understanding the inventive concept of the present disclosure, the memory cells MC are illustrated as being exposed over the column interconnection lines CL.

The semiconductor device may include a cell area CA, a first peripheral circuit area PA1, and a second peripheral circuit area PA2. The first peripheral circuit area PA1 may be disposed adjacent to a first side of the cell area CA in the first direction X. For example, the first peripheral circuit area PA1 may include a row interconnection line drive circuit. The second peripheral circuit area PA2 may be disposed adjacent to the first side of the cell area CA in the second direction Y. For example, the second peripheral circuit area PA2 may include a column interconnection line drive circuit. Accordingly, the row interconnection lines RL may extend from the first peripheral circuit area PA1 in the first direction X and pass through the cell area CA. The column interconnection lines CL may extend from the second peripheral circuit area PA2 in the second direction Y and pass through the cell area CA. The row interconnection lines RL and the column interconnection lines CL may intersect with each other in the cell area CA. According to an embodiment of the present disclosure, the row interconnection lines RL may correspond to word lines, and the column interconnection lines CL may correspond to bit lines. According to another embodiment of the present disclosure, the row interconnection lines RL may correspond to the bit lines, and the column interconnection lines CL may correspond to the word lines.

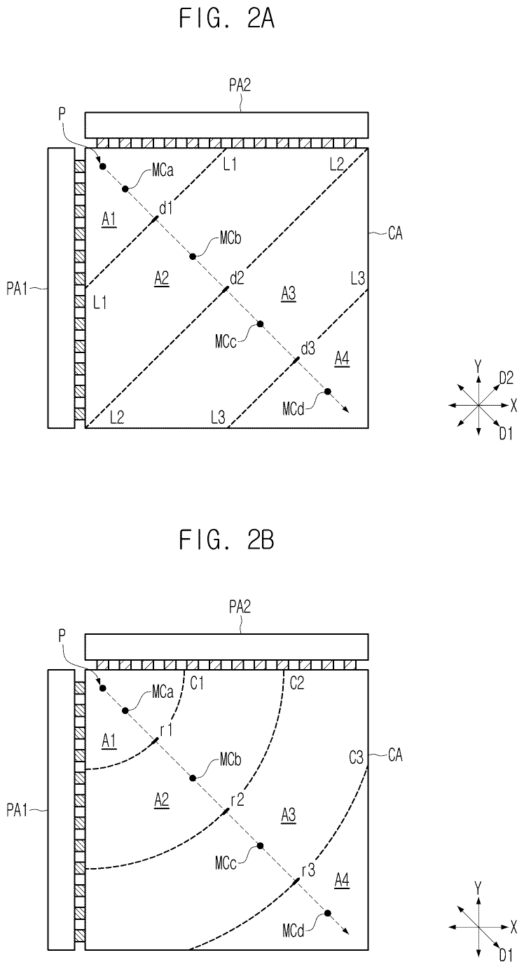

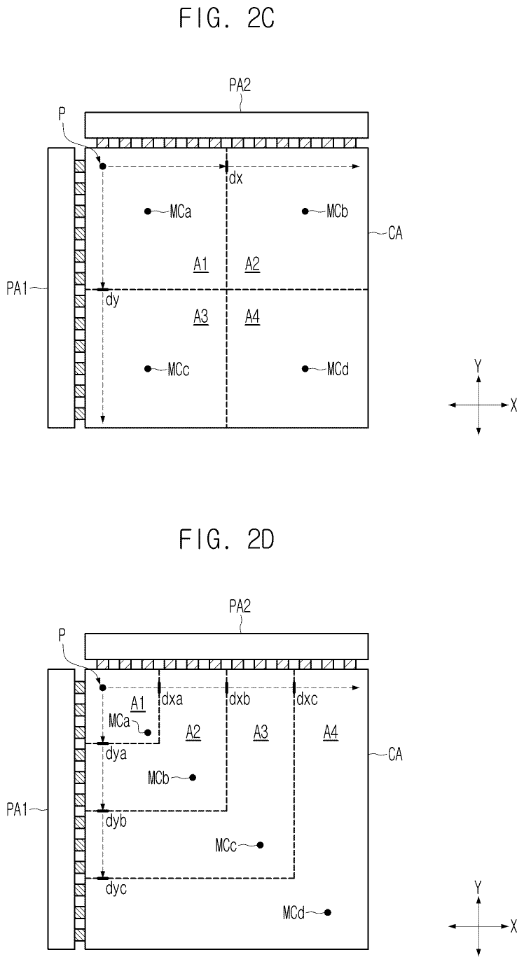

FIGS. 2A to 2D illustrate a cell area CA of a semiconductor device including a plurality of sub-areas A1 to A4 in accordance with embodiments of the present disclosure. For example, one cell area CA may be virtually divided into a plurality of sub-areas A1 to A4. That is, the cell area may include a plurality of sub-areas A1 to A4. Referring to FIGS. 2A to 2C, the cell area CA may include a plurality of sub-areas A1 to A4. The sub-areas A1 to A4 may be divided according to spacing distances d1 to d3, r1 to r3, and dx to dy from a reference point P. The reference point P may be a memory cell MC disposed closest to the first peripheral circuit area PA1 and the second peripheral circuit area PA2 in the cell area CA. For example, the reference point P may be disposed adjacent to a first corner of the cell area CA. The first corner may be closest to the first and the second peripheral circuit areas PA1 and PA2.

Referring to FIG. 2A, the cell area CA may include a plurality of sub-areas A1 to A4 that are divided by a plurality of boundary lines L1, L2, and L3 (simply referred to as L1 to L3). The boundary lines L1 to L3 may extend in a second diagonal direction D2 to have a first shortest spacing distance d1, a second shortest spacing distance d2, and a third shortest spacing distance d3 from the reference point P in the first diagonal direction D1. Accordingly, the first sub-area A1 may include memory cells MCa that are disposed in the first boundary line L1 from the reference point P, and the second sub-area A2 may include memory cells MCb that are disposed in the first boundary line L1 and the second boundary line L2 from the reference point P, and the third sub-area A3 may include memory cells MCc that are disposed in the second boundary line L2 and the third boundary line L3 from the reference point P, and the fourth sub-area A4 may include memory cells MCc that are disposed in the outside of the third boundary line L3 from the reference point P. According to an embodiment of the present disclosure, the boundary lines L1 to L3 may have a serpentine shape so as not to cross the memory cells MC from a microscopic perspective.

Referring to FIG. 2B, the cell area CA may include a plurality of sub-areas A1 to A4 (e.g., A1, A2, A3, and A4) that are divided by a plurality of concentric circle-shaped boundary curves C1 to C3. The boundary curves C1 to C3 may have a concentric circular arc shape centering around the reference point P. Accordingly, the sub-areas A1 to A4 may have a sector shape or a track sector shape. The first sub-area A1 may include memory cells MCa that are disposed in a first boundary curve C1 having a radius of a first spacing distance r1 in the diagonal direction D1 from the reference point P. The second sub-area A2 may include memory cells MCb that are disposed in the first boundary curve C1 having a radius of the first spacing distance r1 from the reference point P and the second boundary curve C2 having a radius of the second spacing distance r2. The third sub-area A3 may include memory cells MCc that are disposed in the second boundary curve C2 having a radius of a second spacing distance r2 from the reference point P and the third boundary curve C3 having a radius of the third spacing distance r3. The fourth sub-area A4 may include memory cells MCc that are disposed in the outside of the third boundary curve C3 having a radius of the third spacing distance r3 from the reference point P. The boundary curves C1 to C3 may also have a serpentine shape so as not to cross the memory cells MC from the microscopic perspective.

Referring to FIG. 2C, the cell area CA may include a plurality of sub-areas A1 to A4 that are divided based on a predetermined distance dx and dy in the first direction X and the second direction Y from the reference point P. The cell areas A1 to A4 may include a first sub-area A1 including memory cells MCa that are disposed within a first distance dx in the first direction X and a second distance dy in the second direction Y from the reference point P, a second sub-area A2 including memory cells MCb that are disposed over the first distance dx in the first direction X and within the second distance dy in the second direction Y from the reference point P, a third sub-area A3 including memory cells MCc that are disposed within the first distance dx in the first direction X and over the second distance dy in the second direction Y from the reference point P, and a fourth sub-area A4 including memory cells MCd that are disposed over the first distance dx in the first direction X and over the second distance dy in the second direction Y from the reference point P.

Referring to FIG. 2D, the cell area CA may include a plurality of sub-areas A1 to A4 (A1, A2, A3, and A4) that are divided based on a first distance dxa, a second distance dxb, and a third distance dxc in the first direction X from the reference point P, and based on a first distance dya, a second distance dyb, and a third distance dyc in the second direction Y. The cell areas A1 to A4 may include a first sub-area A1 including memory cells MCa that are disposed within the first distance dxa in the first direction X and the first distance dya in the second direction Y from the reference point P, a second sub-area A2 including memory cells MCb that are disposed over the first distance dxa and within the second distance dxb in the first direction X from the reference point P, and over the first distance dya and within the second distance dyb in the second direction Y, a third sub-area A3 including memory cells MCb that are disposed over the second distance dxb and within the third distance dxc in the first direction X from the reference point P, and over the second distance dyb and within the third distance dyc in the second direction Y from the reference point P, and a fourth sub-area A4 including memory cells MCb that are disposed over the third distance dxc in the first direction X from the reference point P and over the third distance dyc in the second direction Y from the reference point P.

According to the technical concepts of the present disclosure, the cell area CA may include at least two or more sub-areas A1 to A4. The cell area CA may be divided into at least two or more sub-areas. According to the technical concepts of the present disclosure, the cell area CA may be divided into a plurality of sub-areas A1 to A4 from the area A1 closest to the reference point P to the area A4 farthest from the reference point P.

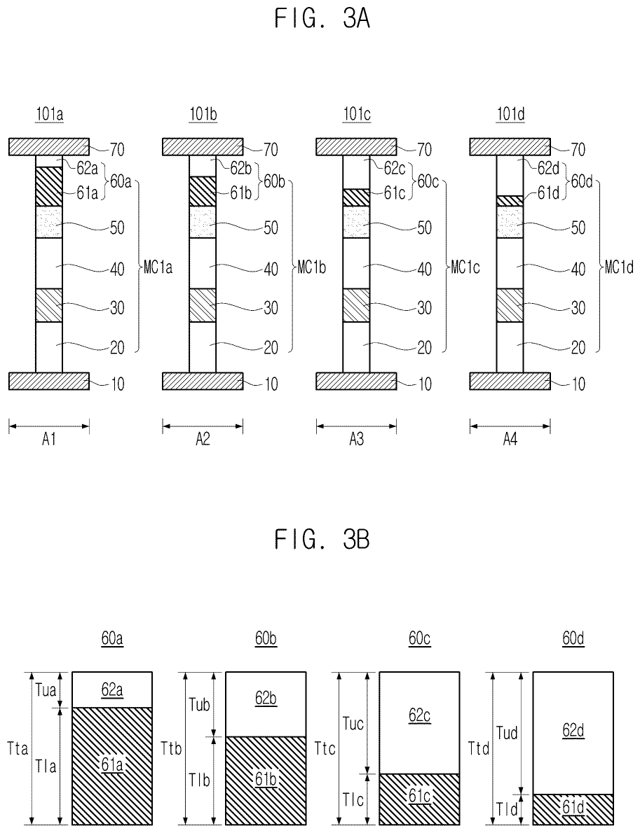

FIGS. 3A and 3B, FIGS. 4A and 4B, FIGS. 5A and 5B, and FIG. 6 are cross-sectional views and enlarged views illustrating memory cell structures 101a to 101d, 102a to 102d, 103a to 103d, and 104a to 104d of semiconductor devices in accordance with diverse embodiments of the present disclosure.

Referring to FIGS. 3A and 3B, the semiconductor device in accordance with one embodiment of the present disclosure may include first to fourth memory cell structures 101a to 101d. Each of the first to fourth memory cell structures 101a to 101d may include a lower interconnection line 10, memory cells MC1a to MC1d disposed over the lower interconnection line 10, and an upper interconnection line 70 disposed over the memory cells MC1a to MC1d.

The lower interconnection line 10 may correspond to the row interconnection lines RL of FIGS. 1A and 1B. The upper interconnection line 70 may correspond to the column interconnection lines CL of FIGS. 1A and 1B. Each of the lower interconnection lines 10 and the upper interconnection lines 70 may include at least one among a metal layer such as tungsten (W), a metal compound layer such as titanium nitride (TiN), a metal alloy layer, and a metal silicide layer.

Referring to FIGS. 2A to 2C, the first memory cell structure 101a may be disposed in the first sub-area A1, and the second memory cell structure 101b may be disposed in the second sub-area A2, and the third memory cell structure 101c may be disposed in the third sub-area A3, and the fourth memory cell structure 101d may be disposed in the fourth sub-area A4.

The first memory cell MC1a may include a bottom electrode 20, a selection element 30, an intermediate electrode 40, a variable resistance element 50, and a first top electrode 60a. The first top electrode 60a may include a first lower top electrode 61a and a first upper top electrode 62a. The second memory cell MC1b may include a bottom electrode 20, a selection element 30, an intermediate electrode 40, a variable resistance element 50, and a second top electrode 60b. The second top electrode 60b may include a second lower top electrode 61b and a second upper top electrode 62b. The third memory cell MC1c may include a bottom electrode 20, a selection element 30, an intermediate electrode 40, a variable resistance element 50, and a third top electrode 60c. The third top electrode 60c may include a third lower top electrode 61c and a third upper top electrode 62c. The fourth memory cell MC1d may include a bottom electrode 20, a selection element 30, an intermediate electrode 40, a variable resistance element 50, and a fourth top electrode 60d. The fourth top electrode 60d may include a fourth lower top electrode 61d and a fourth upper top electrode 62d.

The bottom electrode 20 may include at least one among a metal layer such as tungsten (W), a metal compound layer such as titanium nitride (TiN), a metal alloy layer, and a metal silicide layer. The selection element 30 may include an Ovonic Threshold Switching (OTS) material such as a chalcogenide-based material, a Mixed Ionic Electronic Conducting (MIEC) material such as a metal-containing chalcogenide-based material, a Metal-Insulator Transition (MIT) material such as niobium oxide (NbO₂) or vanadium oxide (VO₂), or an ion-doped dielectric layer. According to an embodiment of the present disclosure, the selection element 30 may include arsenic (As)-doped silicon oxide (SiO₂) or arsenic (As)-doped silicon nitride (SiN). The intermediate electrode 40 may include a carbon layer. The variable resistance element 50 may include one among a transition metal oxide layer, a metal oxide layer such as a perovskite-based material, a phase change material layer such as a chalcogenide-based material, a ferroelectric material layer, and a ferromagnetic material layer. In all memory cells MC1a to MC1d of all memory structures 101a to 101d, the bottom electrodes 20 may have the same vertical thickness.

The first to fourth lower top electrodes 61a to 61d may include a carbon layer, an ion-doped carbon layer, or an ion-doped titanium nitride layer. For example, the ions may include at least one of arsenic (As), germanium (Ge), silicon (Si), nitrogen (N), and oxygen (O). The first to fourth upper top electrodes 62a to 62d may include a metal layer, such as a tungsten (W) layer, or a metal compound layer, such as a titanium nitride (TiN) layer.

FIG. 3B is an enlarged view of the first to fourth top electrodes 60a to 60d of FIG. 3A. Referring to FIG. 3B, the first lower top electrode 61a of the first top electrode 60a may have a first lower thickness Tla, and the second lower top electrode 62b of the second top electrode 60b may have a second lower thickness Tlb. The third lower top electrode 61c of the third top electrode 60c may have a third lower thickness Tlc, and the fourth lower top electrode 61d of the fourth top electrode 60d may have a fourth lower thickness Tld. The first lower thickness Tla may be thicker than the second lower thickness Tlb. The second lower thickness Tlb may be thicker than the third lower thickness Tlc. The third lower thickness Tlc may be thicker than the fourth lower thickness Tld. According to an embodiment of the present disclosure, the second lower thickness Tlb and the third lower thickness Tlc may be substantially the same.

Also, the first upper top electrode 62a of the first top electrode 60a may have a first upper thickness Tua, and the second upper top electrode 62b of the second top electrode 60b may have a second upper thickness Tub. The third upper top electrode 62c of the third top electrode 60c may have a third upper thickness Tuc, and the fourth upper top electrode 62d of the fourth top electrode 60d may have a fourth upper thickness Tud. The first upper thickness Tua may be thinner than the second upper thickness Tub, the second upper thickness Tub may be thinner than the third upper thickness Tuc, and the third upper thickness Tuc may be thinner than the fourth upper thickness Tud. According to an embodiment of the present disclosure, the second upper thickness Tub and the third upper thickness Tuc may be substantially the same.

The sum Tta of the first lower thickness Tla and the first upper thickness Tua, the sum Ttb of the second lower thickness Tlb and the second upper thickness Tub, the sum Ttc of the third lower thickness Tlc and the third upper thickness Tuc, and the sum Ttd of the fourth lower thickness Tld and the fourth upper thickness Tud may be the same. In the illustrated embodiment, the total thicknesses Tta, Ttb, Ttc, and Ttd of each of the first, second, third, and fourth top electrodes 60a, 60b, 60c, and 60d may be the same.

Each of the lower top electrodes 61a to 61d may have a resistance which is sufficiently higher than those of the upper top electrodes 62a to 62d. The upper top electrodes 62a to 62d may have a very low resistance, i.e., high conductivity. The upper top electrodes 62a to 62d may have various thicknesses Tua to Tud, but they may have little difference in their resistances. The upper top electrodes 62a to 62d may not affect the resistance of the top electrodes 60a to 60d. Therefore, the first top electrode 60a may have a resistance which is higher than that of the second top electrode 60b. The second top electrode 60b may have a resistance which is higher than that of the third top electrode 60c. The third top electrode 60c may have a resistance which is higher than that of the fourth top electrode 60d.

Each of the first peripheral circuit area PA1 and/or the second peripheral circuit area PA2 may have driving circuits. Therefore, the first peripheral circuit area PA1 and/or the second peripheral circuit area PA2 may supply a voltage or current to the memory cells MC1a to MC1d in the cell area CA. A memory cell close to the first peripheral circuit area PA1 and/or the second peripheral circuit area PA2, for example, the first memory cell MC1a, may be provided with a relatively high voltage or current. Accordingly, the memory cell which is close to the first peripheral circuit area PA1 and/or the second peripheral circuit area PA2, for example, the first memory cell MC1a, may have a hold current which is higher than that of a memory cell which is far from the first peripheral circuit area PA1 and/or the second peripheral circuit area PA2, for example, the fourth memory cell MC1d. Therefore, a phenomenon in which the hold current “I-hold” becomes higher than the cell current Ic may occur in the memory cell which is close to the first peripheral circuit area PA1 and/or the second peripheral circuit area PA2, for example, the first memory cell MC1a. Although the selection element 30 is turned off in the memory cell close to the first peripheral circuit area PA1 and/or the second peripheral circuit area PA2, for example, the first memory cell MC1a, a current which is higher than the current of a turn-on state may flow in the memory cell MC1a. Accordingly, an oscillation phenomenon in which the current value of the current repeats between the on/off states in the region between the threshold current Ith and the hold current I-hold of the selection element 30 in the memory cell close to the first peripheral circuit area PA1 and/or the second peripheral circuit area PA2, for example, the first memory cell MC1a, may occur. According to an embodiment of the present disclosure, the resistance of the top electrodes 60a to 60d may vary according to the positions of the memory cells MC1a to MC1d. For example, the first top electrode 60a of the memory cell that is the closest to the first peripheral circuit area PA1 and/or the second peripheral circuit area PA2, for example, the first memory cell MC1a, may have a relatively high resistance, and the fourth top electrode 60d of the memory cell that is the farthest from the first peripheral circuit area PA1 and/or the second peripheral circuit area PA2, for example, the fourth memory cell MC1d, may have a relatively low resistance. Overall, the hold current I-hold of the memory cells MC1a to MC1d may become uniform, and the operation of the memory cells MC1a to MC1d may be stable. In FIGS. 3A and 3B, the positions and/or resistances of the lower top electrodes 61a to 61d and the upper top electrodes 62a to 62d may be switched with each other.

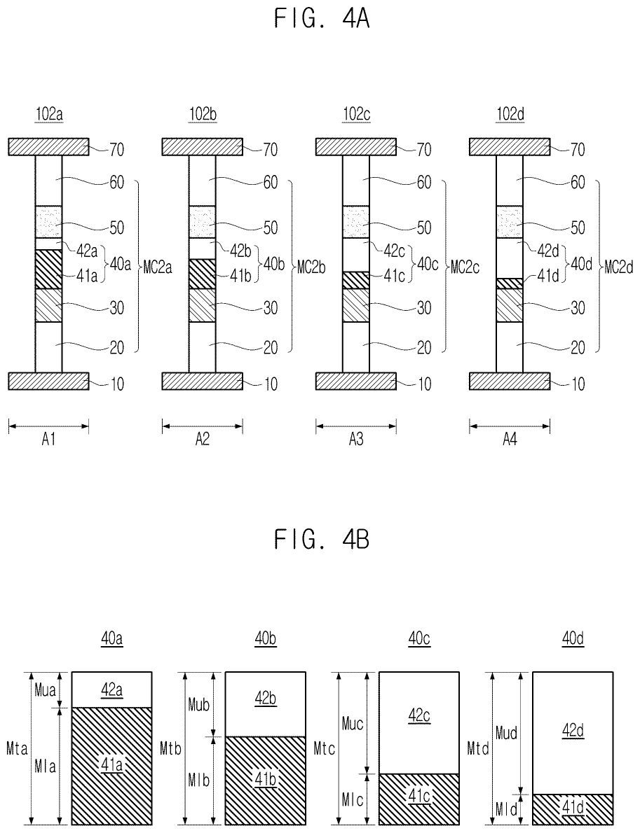

Referring to FIGS. 4A and 4B, the semiconductor device in accordance with an embodiment of the present disclosure may include first to fourth memory cell structures 102a to 102d. Each of the first to fourth memory cell structures 102a to 102d may include a lower interconnection line 10, memory cells MC2a to MC2d disposed over the lower interconnection line 10, and an upper interconnection line 70 disposed over the memory cells MC2a to MC2d.

Referring to FIGS. 2A to 2C, the first memory cell structure 102a may be disposed in the first sub-area A1, and the second memory cell structure 102b may be disposed in the second sub-area A2, and the third memory cell structure 102c may be disposed in the third sub-area A3, and the fourth memory cell structure 102d may be disposed in the fourth sub-area A4.

The first memory cell MC2a may include a bottom electrode 20, a selection element 30, a first intermediate electrode 40a, a variable resistance element 50, and a top electrode 60. The first intermediate electrode 40a may include a first lower intermediate electrode 41a and a first upper intermediate electrode 42a. The second memory cell MC2b may include a bottom electrode 20, a selection element 30, a second intermediate electrode 40b, a variable resistance element 50, and a top electrode 60. The second intermediate electrode 40b may include a second lower intermediate electrode 41b and a second upper intermediate electrode 42b. The third memory cell MC2c may include a bottom electrode 20, a selection element 30, a third intermediate electrode 40c, a variable resistance element 50, and a top electrode 60. The third intermediate electrode 40c may include a third lower intermediate electrode 41c and a third upper intermediate electrode 42c. The fourth memory cell MC2d may include a bottom electrode 20, a selection element 30, a fourth intermediate electrode 40d, a variable resistance element 50, and a top electrode 60. The fourth intermediate electrode 40d may include a fourth lower intermediate electrode 41d and a fourth upper intermediate electrode 42d. The first to fourth lower intermediate electrodes 41a to 41d may include a carbon layer. The first to fourth upper intermediate electrodes 42a to 42d may include a metal compound layer such as titanium nitride (TiN) or a metal layer such as tungsten (W).

FIG. 4B is an enlarged view of the first to fourth intermediate electrodes 40a to 40d shown in FIG. 4A. Referring to FIG. 4B, the first lower intermediate electrode 41a of the first intermediate electrode 40a may have a first lower thickness Mla, the second lower intermediate electrode 41b of the second intermediate electrode 40b may have a second lower thickness Mlb, the third lower intermediate electrode 41c of the third intermediate electrode 40c may have a third lower thickness Mlc, and the fourth lower intermediate electrode 41d of the fourth intermediate electrode 40d may have a fourth lower thickness Mld. The first lower thickness Mla may be thicker than the second lower thickness Mlb, the second lower thickness Mlb may be thicker than the third lower thickness Mlc, and the third lower thickness Mlc may be thicker than the fourth lower thickness Mld. According to an embodiment of the present disclosure, the second lower thickness Mlb and the third lower thickness Mlc may be substantially the same.

Also, the first upper intermediate electrode 42a of the first intermediate electrode 40a may have a first upper thickness Mua, the second upper intermediate electrode 42b of the second intermediate electrode 40b may have a second upper thickness Mub, the third upper intermediate electrode 42c of the third intermediate electrode 40c may have a third upper thickness Muc, and the fourth upper intermediate electrode 42d of the fourth intermediate electrode 40d may have a fourth upper thickness Mud. The first upper thickness Mua may be thinner than the second upper thickness Mub. The second upper thickness Mub may be thinner than the third upper thickness Muc. The third upper thickness Muc may be thinner than the fourth upper thickness Mud. According to an embodiment of the present disclosure, the second upper thickness Mub and the third upper thickness Muc may be substantially the same.

The sum Mta of the first lower thickness Mla and the first upper thickness Mua, the sum Mtb of the second lower thickness Mlb and the second upper thickness Mub, the sum Mtc of the third lower thickness Mlc and the third upper thickness Muc, and the sum Mtd of the fourth lower thickness Mld and the fourth upper thickness Mud may be the same. In the illustrated embodiment, the total thicknesses Mta, Mtb, Mtc, and Mtd of the first to fourth intermediate electrodes 40a, 40b, 40c, and 40d may be the same.

Each of the lower intermediate electrodes 41a to 41d may have a resistance which is higher than those of the upper intermediate electrodes 42a to 42d. Accordingly, the first intermediate electrode 40a may have a resistance which is higher than that of the second top electrode 40b, the second intermediate electrode 40b may have a resistance which is higher than that of the third intermediate electrode 40c, and the third intermediate electrode 40c may have a resistance which is higher than that of the fourth intermediate electrode 40d.

Each of the lower intermediate electrodes 41a to 41d may have a resistance which is sufficiently higher than those of the upper intermediate electrodes 42a to 42d. The upper intermediate electrodes 42a to 42d may have a very low resistance, i.e., high conductivity. The upper intermediate electrodes 42a to 42d may have various thicknesses Mua to Mud, but there may be little difference in their resistances. The upper intermediate electrodes 42a to 42d may not affect the resistance of the intermediate electrodes 40a to 40d. Therefore, the first intermediate electrode 40a may have a resistance which is higher than that of the second intermediate electrode 40b. The second intermediate electrode 40b may have a resistance which is higher than that of the third intermediate electrode 40c. The third intermediate electrode 40c may have a resistance which is higher than that of the fourth intermediate electrode 40d. According to an embodiment of the present disclosure, the resistance of the intermediate electrodes 40a to 40d may vary according to the positions of the memory cells MC2a to MC2d. For example, the first top electrode 60a of the memory cell closest to the first peripheral circuit area PA1 and/or the second peripheral circuit area PA2, for example, the first memory cell MC2a, may have a relatively high resistance, and the fourth top electrode 60d of the memory cell farthest from the first peripheral circuit area PA1 and/or the second peripheral circuit area PA2, for example, the fourth memory cell MC2d, may have a relatively low resistance. Overall, the hold current I-hold of the memory cells MC2a to MC2d may become uniform, and the memory cells MC2a to MC2d may operate stably. In FIGS. 4A and 4B, the positions and/or resistances of the lower intermediate electrodes 41a to 41d and the upper intermediate electrodes 42a to 42d may be switched with each other.

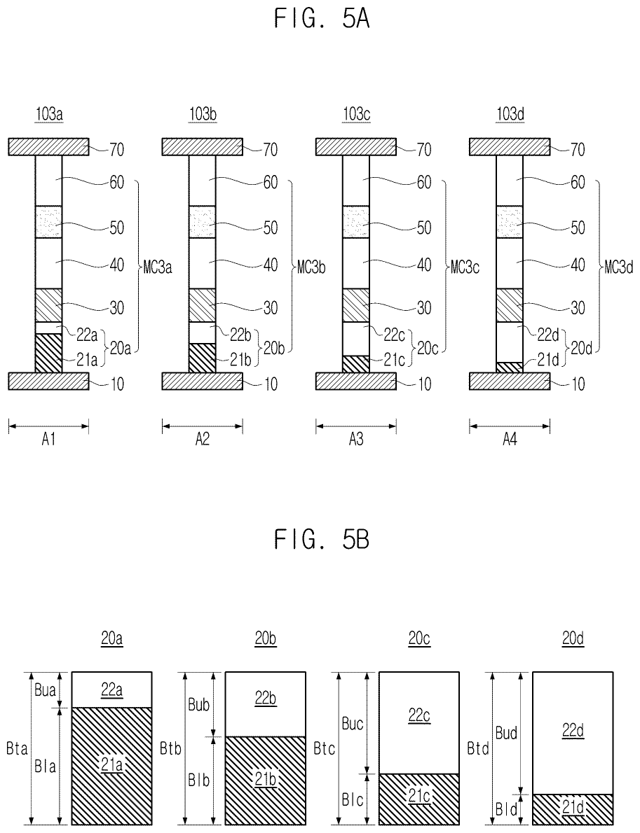

Referring to FIGS. 5A and 5B, the semiconductor device in accordance with an embodiment of the present disclosure may include first to fourth memory cell structures 103a to 103d. Each of the first to fourth memory cell structures 103a to 103d may include a lower interconnection line 10, memory cells MC3a to MC3d over the lower interconnection line 10, and an upper interconnection line 70 over the memory cells MC3a to MC3d.

Referring to FIGS. 2A to 2C, the first memory cell structure 103a may be disposed in the first sub-area A1, the second memory cell structure 103b may be disposed in the second sub-area A2, the third memory cell structure 103c may be disposed in the third sub-area A3, and the fourth memory cell structure 103d may be disposed in the fourth sub-area A4.

The first to fourth memory cells MC3a to MC3d may include first to fourth bottom electrodes 20a, 20b, 20c, and 20d, respectively. Also, the first to fourth bottom electrodes 20a, 20b, 20c, and 20d may include first to fourth lower bottom electrodes 21a, 21b, 21c, and 21d, respectively. Furthermore, the first to fourth bottom electrodes 20a, 20b, 20c, and 20d may include first to fourth upper bottom electrodes 22a, 22b, 22c, and 22d, respectively. More specifically, the first memory cell MC3a may include a first bottom electrode 20a, a selection element 30, an intermediate electrode 40, a variable resistance element 50, and a top electrode 60. The first bottom electrode 20a may include a first lower bottom electrode 21a and a first upper bottom electrode 22a. The second memory cell MC3b may include a second bottom electrode 20b, a selection element 30, an intermediate electrode 40, a variable resistance element 50, and a top electrode 60. The second bottom electrode 20b may include a second lower bottom electrode 21b and a second upper bottom electrode 22b. The third memory cell MC3c may include a third bottom electrode 20c, a selection element 30, an intermediate electrode 40, a variable resistance element 50, and a top electrode 60. The third bottom electrode 20c may include a third lower bottom electrode 21c and a third upper bottom electrode 22c. The fourth memory cell MC4d may include a fourth bottom electrode 20d, a selection element 30, an intermediate electrode 40, a variable resistance element 50, and a top electrode 60. The fourth bottom electrode 20d may include a fourth lower bottom electrode 21d and a fourth upper bottom electrode 22d. The first to fourth lower bottom electrodes 21a to 21d may include a carbon layer. The first to fourth upper bottom electrodes 22a to 22d may include a metal compound layer such as titanium nitride (TiN) or a metal layer such as tungsten (W).

FIG. 5B is an enlarged view of the first to fourth bottom electrodes 20a to 20d of FIG. 5A. Referring to FIG. 5B, the first to fourth lower bottom electrodes 21a, 21b, 21c, and 21d of the first bottom electrode 20a may have first to fourth lower thicknesses Bla, Blb, Blc, and Bld, respectively. More specifically, the first lower bottom electrode 21a of the first bottom electrode 20a may have a first lower thickness Bla, the second lower bottom electrode 21b of the second bottom electrode 20b may have a second lower thickness Blb, the third lower bottom electrode 21c of the third bottom electrode 20c may have a third lower thickness Blc, and the fourth lower bottom electrode 21d of the fourth bottom electrode 20d may have a fourth lower thickness Bld. The first lower thickness Bla may be thicker than the second lower thickness Blb, the second lower thickness Blb may be thicker than the third lower thickness Blc, and the third lower thickness Blc may be thicker than the fourth lower thickness Bld. According to an embodiment of the present disclosure, the second lower thickness Blb and the third lower thickness Blc may be substantially the same.

Also, the first upper bottom electrode 22a of the first bottom electrode 20a may have a first upper thickness Bua, the second upper bottom electrode 22b of the second bottom electrode 20b may have a second upper thickness Bub, the third upper bottom electrode 22c of the third bottom electrode 20c may have a third upper thickness Buc, and the fourth upper bottom electrode 22d of the fourth bottom electrode 20d may have a fourth upper thickness Bud. The first upper thickness Bua may be thinner than the second upper thickness Bub. The second upper thickness Bub may be thinner than the third upper thickness Buc. The third upper thickness Buc may be thinner than the fourth upper thickness Bud. According to an embodiment of the present disclosure, the second upper thickness Bub and the third upper thickness Buc may be substantially the same.

The sum Bta of the first lower thickness Bla and the first upper thickness Bua, the sum Btb of the second lower thickness Blb and the second upper thickness Bub, the sum Btc of the third lower thickness Blc and the third upper thickness Buc, and the sum Btd of the fourth lower thickness Bld and the fourth upper thickness Bud may be the same. The total thicknesses of the first to fourth bottom electrodes 20a, 20b, 20c, and 20d may be the same.

Each of the lower bottom electrodes 21a to 21d may have a sufficiently high resistance which is higher than those of the upper bottom electrodes 22a to 22d. The upper bottom electrodes 22a to 22d may have a very low resistance, i.e., high conductivity. The upper bottom electrodes 22a to 22d may have various thicknesses Bua to Bud, but there may be little difference in their resistances. The upper bottom electrodes 22a to 22d may not affect the resistance of the bottom electrodes 20a to 20d. Therefore, the first bottom electrode 20a may have a resistance which is higher than that of the second bottom electrode 20b, the second bottom electrode 20b may have a resistance which is higher than that of the third bottom electrode 20c, and the third bottom electrode 20c may have a resistance which is higher than that of the fourth bottom electrode 20d. According to an embodiment of the present disclosure, the resistance of the bottom electrodes 20a to 20d may vary according to the positions of the memory cells MC3a to MC3d. For example, the first bottom electrode 20a of the memory cell that is closest to the first peripheral circuit area PA1 and/or the second peripheral circuit area PA2, for example, the first memory cell MC3a, may have a relatively high resistance, and the fourth bottom electrode 20d of the memory cell farthest from the first peripheral circuit area PA1 and/or the second peripheral circuit area PA2, for example, the fourth memory cell MC3d, may have a relatively low resistance. Overall, the hold current I-hold of the memory cells MC3a to MC3d may become uniform, and the memory cells MC3a to MC3d may operate stably. In FIGS. 5A and 5B, the positions and/or resistances of the lower bottom electrodes 21a to 21d and the upper bottom electrodes 22a to 22d may be switched with each other.

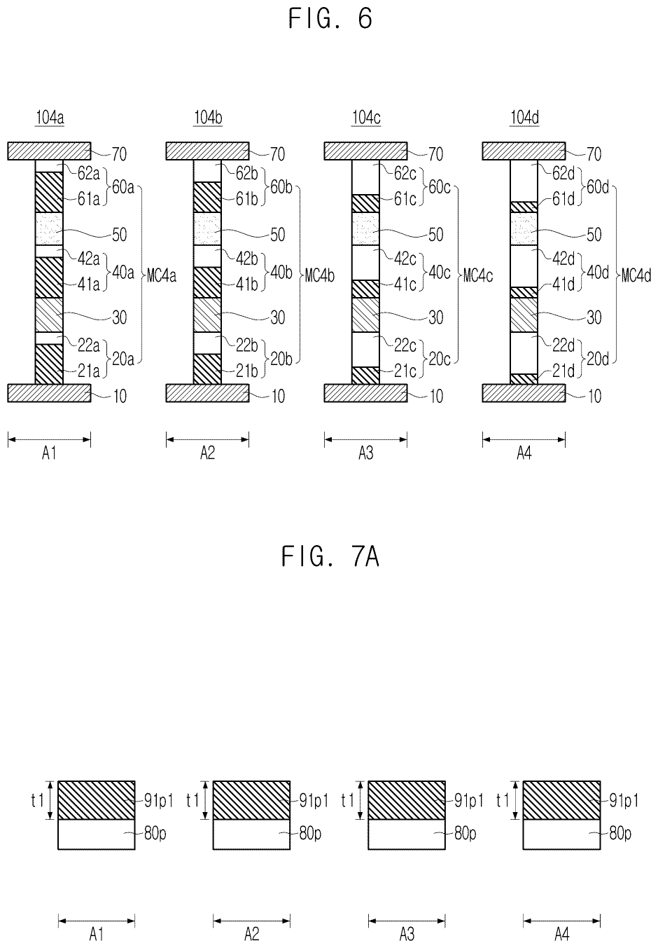

Referring to FIG. 6, a semiconductor device in accordance with an embodiment of the present disclosure may include first to fourth memory cell structures 104a to 104d. Each of the first to fourth memory cell structures 104a to 104d may include memory cells MC4a to MC4d disposed over the lower interconnection line 10, and an upper interconnection line 70 disposed over the memory cells MC4a to MC4d. Referring to FIGS. 2A to 2C, the first memory cell structure 104a may be disposed in the first sub-area A1, the second memory cell structure 104b may be disposed in the second sub-area A2, the third memory cell structure 104c may be disposed in the third sub-area A3, and the fourth memory cell structure 104d may be disposed in the fourth sub-area A4.

The first to fourth memory cells MC4a, MC4b, MC4c, and MC4d may include first, to fourth bottom electrodes 20a, 20b, 20c, and 20d, respectively. Moreover, the first to fourth memory cells MC4a, MC4b, MC4c, and MC4d may also include first to fourth intermediate electrodes 40a, 40b, 40c, and 40d, respectively. Furthermore, the first to fourth memory cells MC4a, MC4b, MC4c, and MC4d may also include first to fourth top electrodes 60a, 60b, 60c, and 60d, respectively.

The first memory cell MC4a may include a first bottom electrode 20a, a selection element 30, a first intermediate electrode 40a, a variable resistance element 50, and a first top electrode 60a. The first bottom electrode 20a may include a first lower bottom electrode 21a and a first upper bottom electrode 22a. The first intermediate electrode 40a may include a first lower intermediate electrode 41a and a first upper intermediate electrode 42a. The first top electrode 60a may include a first lower top electrode 61a and a first upper top electrode 62a.

The second memory cell MC4b may include a second bottom electrode 20b, a selection element 30, a second intermediate electrode 40b, a variable resistance element 50, and a second top electrode 60b. The second bottom electrode 20b may include a second lower bottom electrode 21b and a second upper bottom electrode 22b. The second intermediate electrode 40b may include a second lower intermediate electrode 41b and a second upper intermediate electrode 42b. The second top electrode 60b may include a second lower top electrode 61b and a second upper top electrode 62b.

The third memory cell MC4c may include a third bottom electrode 20c, a selection element 30, a third intermediate electrode 40c, a variable resistance element 50, and a third top electrode 60c. The third bottom electrode 20c may include a third lower bottom electrode 21c and a third upper bottom electrode 22c. The third intermediate electrode 40c may include a third lower intermediate electrode 41c and a third upper intermediate electrode 42c. The third top electrode 60c may include a third lower top electrode 61c and a third upper top electrode 62c.

The fourth memory cell MC4d may include a fourth bottom electrode 20d, a selection element 30, a fourth intermediate electrode 40d, a variable resistance element 50, and a fourth top electrode 60d. The fourth bottom electrode 20d may include a fourth lower bottom electrode 21d and a fourth upper bottom electrode 22d. The fourth intermediate electrode 40d may include a fourth lower intermediate electrode 41d and a fourth upper intermediate electrode 42d. The fourth top electrode 60d may include a fourth lower top electrode 61d and a fourth upper top electrode 62d.

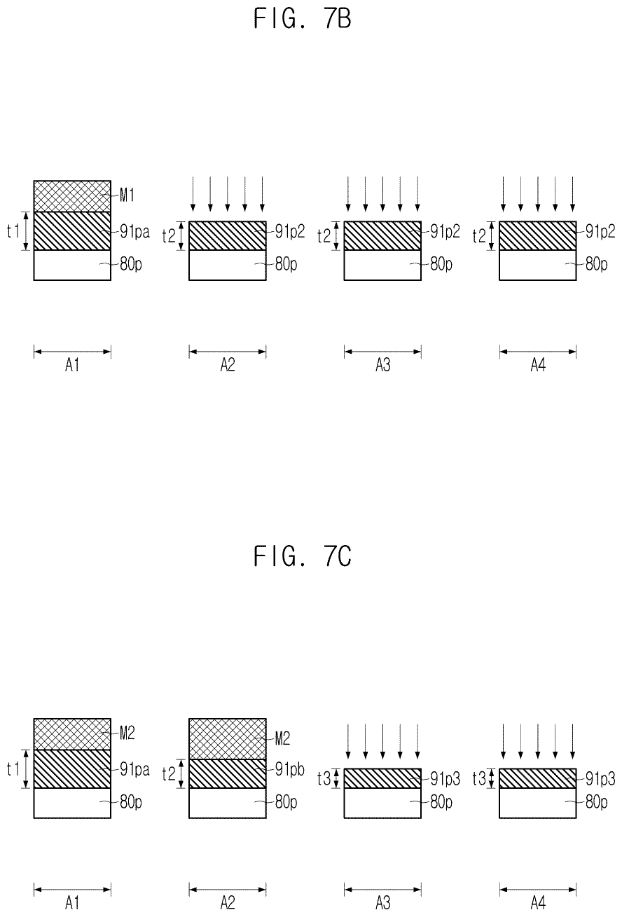

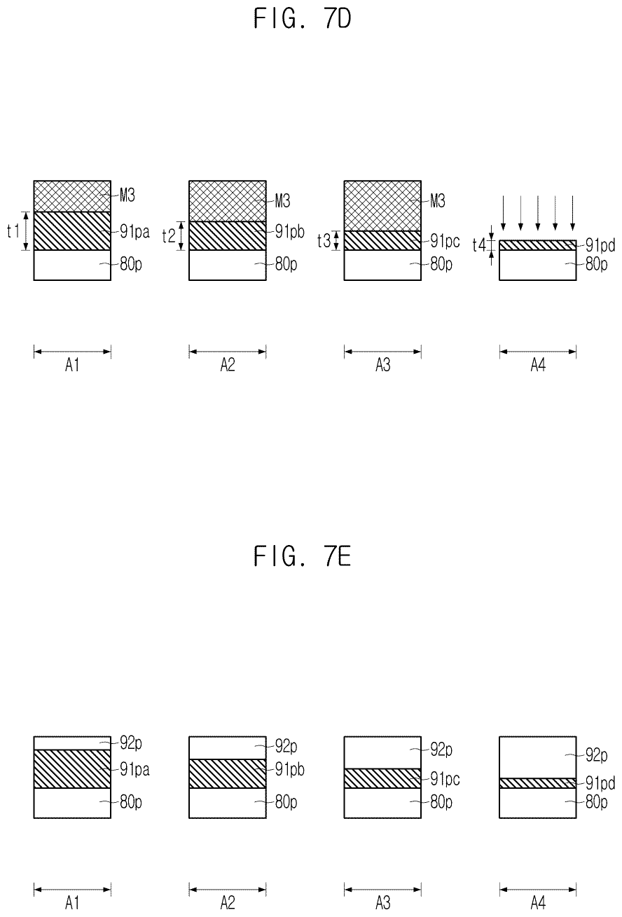

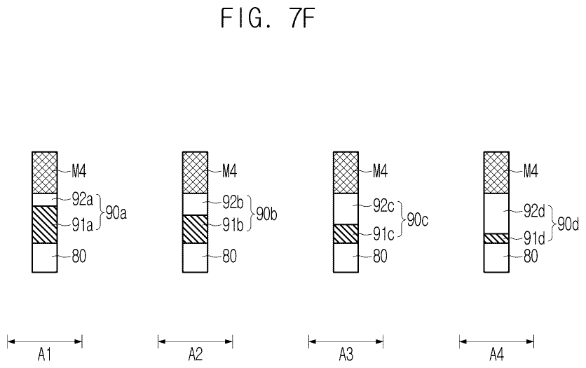

FIGS. 7A to 7F illustrate a method for forming electrode structures 90a to 90d in accordance with an embodiment of the present disclosure. Referring to FIG. 7A, the method for forming electrode structures 90a to 90d in accordance with the embodiment of the present disclosure may include forming a first preliminary lower electrode layer 91p1 over a base layer 80p in the first to fourth sub-areas A1 to A4. The first preliminary lower electrode layer 91p1 may include a carbon layer or a metal compound layer such as titanium nitride. The first preliminary lower electrode layer 91p1 may have a first thickness t1. The base layer 80p may be a material layer for forming one of the lower interconnection line 10, the selection element 30, and the variable resistance element 50.

Referring to FIG. 7B, the method may further include covering the first sub-area A1, forming a first mask pattern M1 that exposes the second to fourth sub-areas A2 to A4, and performing a first etch-back process to partially remove the upper portion of the first preliminary lower electrode layer 91p1 that is exposed in the second to fourth sub-areas A2 to A4. For example, the method may include thinning the first preliminary lower electrode layer 81p1 that is exposed in the second to fourth sub-areas A2 to A4. In the first sub-area A1, the first preliminary lower electrode layer 91p1 may remain as a first lower electrode layer 91pa, and in the second to fourth sub-areas A2 to A4, the first preliminary lower electrode layer 91p1 may become thin into a second preliminary lower electrode layer 91p2 having a second thickness t2. Subsequently, the first mask pattern M1 may be removed.

Referring to FIG. 7C, the method may further include covering the first sub-area A1 and the second sub-area A2, forming a second mask pattern M2 that exposes the third sub-area A3 and the fourth sub-area A4, and performing a second etch-back process to partially remove the upper portions of the second preliminary lower electrode layer 91p2 that are exposed in the third sub-area A3 and the fourth sub-area A4. For example, the method may include thinning the second preliminary lower electrode layer 91p2 that is exposed in the third sub-area A3 and the fourth sub-area A4. The first lower electrode layer 91pa may remain in the first sub-area A1, the second preliminary lower electrode layer 91p2 may remain as a second lower electrode layer 91pb in the second sub-area A2, and the second preliminary lower electrode layer 91p2 may become thin into a third preliminary lower electrode layer 91p3 having a third thickness t3 in the third sub-area A3 and the fourth sub-area A4. Subsequently, the second mask pattern M2 may be removed.

Referring to FIG. 7D, the method may further include covering the first to third sub-areas A1 to A3 by forming a third mask pattern M3 that exposes only the fourth sub-area A4, and performing a third etch-back process to partially remove the upper portion of the third preliminary lower electrode layer 91p3 that is exposed in the fourth sub-area A4. For example, the method may include thinning the third preliminary lower electrode layer 91p3 that is exposed in the fourth sub-area A4. The first lower electrode layer 91pa may remain in the first sub-area A1, the second lower electrode layer 91pb may remain in the second sub-area A2, the third preliminary lower electrode layer 91p3 may remain as a third lower top electrode layer 91pc in the third sub-area A3, and the third preliminary lower electrode layer 91p3 may be thinned into a fourth lower electrode layer 91pd having a fourth thickness t4 in the fourth sub-area A4. Subsequently, the third mask pattern M3 may be removed.

Referring to FIG. 7E, the method may further include forming an upper electrode layer 92p over the lower electrode layers 91pa to 91pd in the respective first to fourth sub-areas A1 to A4. Forming the upper electrode layer 92p may include performing a deposition process and a planarization process, such as Chemical Mechanical Polishing (CMP). The upper electrode layer 92p may include a metal layer, such as tungsten (W). In the first to fourth sub-areas A1 to A4, the upper surface of the upper electrode layer 92p may be flat.

Referring to FIG. 7F, the method may further include forming a fourth mask pattern M4 and forming first to fourth electrode structures 90a to 90d and the base element 80 by patterning the upper electrode layer 92p, the lower electrode layers 91pa to 91pd, and the base layer 80p. The first electrode structure 90a may be formed in the first sub-area A1, the second electrode structure 90b may be formed in the second sub-area A2, the third electrode structure 90c may be formed in the third sub-area A3, and the fourth electrode structure 90d may be formed in the fourth sub-area A4. The fourth mask pattern M4 may include a photoresist and/or a hard mask. The hard mask may include at least one inorganic layer. The fourth mask pattern M4 may be removed.

The first to fourth electrode structures 90a to 90d may correspond to the bottom electrodes 20a to 20d, intermediate electrodes 40a to 40d, or top electrodes 60a to 60d illustrated in FIGS. 3A and 3B to 6. The base element 80 may correspond to the lower interconnection line 10, the selection element 30, or the variable resistance element 50 illustrated in FIGS. 3A and 3B to 6.

According to embodiments of the present disclosure, the hold current of memory cells according to the position of the semiconductor element may be stabilized.

According to embodiments of the present disclosure, the characteristics and operation of the memory cells of the semiconductor element may be uniformized and stabilized.

While the present invention has been described with respect to specific example embodiments, it will be apparent to those skilled in the art that various changes and modifications may be made without departing from the technical concepts and scope of the present disclosure as defined in the following claims. Furthermore, the embodiments may be combined to form additional embodiments.

What is claimed is:

1. A semiconductor device comprising:
a cell area;
a first peripheral circuit area adjacent to a first side of the cell area in a first direction; and
a second peripheral circuit area adjacent to a second side of the cell area in a second direction,
wherein the first direction and the second direction are perpendicular to each other, and
wherein the cell area includes:
a first sub-area including a first memory cell; and
a second sub-area including a second memory cell,
wherein:
the first memory cell includes a first electrode structure,
the second memory cell includes a second electrode structure,
the first electrode structure includes a first lower electrode and a first upper electrode,
the second electrode structure includes a second lower electrode and a second upper electrode,
the first lower electrode is thicker than the second lower electrode, and
the first upper electrode is thinner than the second upper electrode.

2. The semiconductor device of claim 1, wherein the first sub-area is disposed closer to the first peripheral circuit area than the second sub-area.

3. The semiconductor device of claim 1, wherein:
the cell area further includes a third sub-area including a third memory cell,
the third memory cell includes a third electrode structure,
the third electrode structure includes a third lower electrode and a third upper electrode,
the second lower electrode is thicker than the third lower electrode, and
the second upper electrode is thinner than the third upper electrode.

4. The semiconductor device of claim 3, wherein:
the first sub-area is disposed closer to the second peripheral circuit area than the second sub-area, and
the third sub-area is disposed farther from the second peripheral circuit area than from the second sub-area.

5. The semiconductor device of claim 3, wherein:
the cell area further includes a fourth sub-area including a fourth memory cell,
the fourth memory cell includes a fourth electrode structure,
the fourth electrode structure includes a fourth lower electrode and a fourth upper electrode,
the third lower electrode is thicker than the fourth lower electrode, and
the third upper electrode is thinner than the fourth upper electrode.

6. The semiconductor device of claim 1,
wherein the first electrode structure includes:
a first bottom electrode;
a first variable resistance element over the first bottom electrode; and
a first top electrode over the first variable resistance element,
wherein the second electrode structure includes:
a second bottom electrode;
a second variable resistance element over the second bottom electrode; and
a second top electrode over the second variable resistance element,
wherein the first top electrode includes the first lower electrode and the first upper electrode, and
wherein the second top electrode includes the second lower electrode and the second upper electrode.

7. The semiconductor device of claim 6, wherein the first bottom electrode and the second bottom electrode have the same thickness.

8. The semiconductor device of claim 6, wherein:
the first lower electrode and the second lower electrode include at least one of a carbon layer, an ion-doped carbon layer, and an ion-doped titanium nitride layer, and
the first upper electrode and the second upper electrode include one of a metal layer and a metal compound layer.

9. The semiconductor device of claim 6, wherein:
the first electrode structure further includes a first selection element and a first intermediate electrode between the first bottom electrode and the first variable resistance element, and
the second electrode structure further includes a second selection element and a second intermediate electrode between the second bottom electrode and the second variable resistance element.

10. The semiconductor device of claim 9, wherein:
the first selection element and the second selection element include one of an Ovonic Threshold Switching (OTS) material, a Mixed Ionic Electronic Conducting (MIEC) material, a Metal-Insulator Transition (MIT) material, and an ion-doped dielectric layer, and
the first intermediate electrode and the second intermediate electrode include a carbon layer.

11. The semiconductor device of claim 1,
wherein the first electrode structure includes:
a first bottom electrode;
a first variable resistance element over the first bottom electrode; and
a first top electrode over the first variable resistance element,
wherein the second electrode structure includes:
a second bottom electrode;
a second variable resistance element over the second bottom electrode; and
a second top electrode over the second variable resistance element,
wherein the first bottom electrode includes the first lower electrode and the first upper electrode, and
wherein the second bottom electrode includes the second lower electrode and the second upper electrode.

12. The semiconductor device of claim 1, wherein a sum of a thickness of the first lower electrode and a thickness of the first upper electrode is the same as a sum of a thickness of the second lower electrode and a thickness of the second upper electrode.

13. The semiconductor device of claim 1, wherein:
a resistance of the first lower electrode is higher than a resistance of the first upper electrode, and
a resistance of the second lower electrode is higher than a resistance of the second upper electrode.

14. The semiconductor device of claim 1, wherein:
the first upper electrode is directly disposed over the first lower electrode, and
the second upper electrode is directly disposed over the second lower electrode.

15. A semiconductor device comprising:
a cell area, and
a first peripheral circuit area adjacent to a first side of the cell area,
wherein the cell area includes:
a first sub-area including a first memory cell; and
a second sub-area including a second memory cell,
wherein the first memory cell is closer to the first peripheral circuit area than the second memory cell,
wherein:
the first memory cell includes a first variable resistance element and a first electrode,
the second memory cell includes a second variable resistance element and a second electrode,
the first electrode includes a first lower electrode and a first upper electrode,
the second electrode includes a second lower electrode and a second upper electrode,
the first lower electrode is thicker than the second lower electrode, and
the first upper electrode is thinner than the second upper electrode.

16. The semiconductor device of claim 15, further comprising:
a second peripheral circuit area adjacent to a second side of the cell area,
wherein the first memory cell is closer to the second peripheral circuit area than the second memory cell.

17. The semiconductor device of claim 15,
wherein the first memory cell includes:
a first bottom electrode;
a first selection element over the first bottom electrode;
a first intermediate electrode over the first selection element;
the first variable resistance element over the first intermediate electrode; and
the first electrode over the first variable resistance element,
wherein the second memory cell includes:
a second bottom electrode;
a second selection element over the second bottom electrode;
a second intermediate electrode over the second selection element;
the second variable resistance element over the second intermediate electrode; and
the second electrode over the second variable resistance element.

18. The semiconductor device of claim 15,
wherein the first memory cell includes:
a first selection element over the first electrode;
a first intermediate electrode over the first selection element;
the first variable resistance element over the first intermediate electrode; and
the first top electrode over the first variable resistance element,
wherein the second memory cell includes:
a second selection element over the second electrode;
a second intermediate electrode over the second selection element;
the second variable resistance element over the second intermediate electrode; and
the second top electrode over the second variable resistance element.

19. The semiconductor device of claim 15, wherein:
the cell area further includes a third sub-area including a third memory cell,
the third memory cell is farther from the first peripheral circuit area than the second memory cell,
the third memory cell includes a third variable resistance element and a third electrode,
the third electrode includes a third lower electrode and a third upper electrode,
the second lower electrode is thicker than the third lower electrode, and
the second upper electrode is thinner than the third upper electrode.

20. The semiconductor device of claim 15, wherein:
the first lower electrode and the second lower electrode include at least one of a carbon layer, an ion-doped carbon layer, and an ion-doped titanium nitride layer, and
the first upper electrode and the second upper electrode include one of a metal layer and a metal compound layer.
